(19) United States
(12) Patent Application Publication
(10) Pub. No.: US 2010/0126959 A1
(43) Pub. Date: May 27, 2010

(54) INK COMPOSITION FOR ROLL PRINTING PROCESS AND METHOD OF FABRICATING PATTERN ON SUBSTRATE USING THE SAME

(76) Inventors: Sung Hee Kim, Paju-Si (KR); Byung Geol Kim, Goyang-si (KR)

Correspondence Address: BRINKS HOFER GILSON & LIONE, P.O. BOX 10395, CHICAGO, IL, 60610, US

(21) Appl. No.: 12/556,308

(22) Filed: Sep. 9, 2009

(30) Foreign Application Priority Data
Nov. 26, 2008 (KR) 10-2008-0118211

(51) Int. Cl. C30B 33/08; C09D 11/02; B05D 1/28

(52) U.S. Cl. 216/23; 524/270; 427/256

(57) ABSTRACT

An ink composition used in a roll printing process and A method of forming a pattern on a substrate using the same are disclosed. The ink composition used in a roll printing process includes polymer or oligomer, a rosin ester based tackifier, and solvent. The method of forming a pattern on a substrate includes forming an organic film by coating an ink composition on the outer circumferential surface of a roller, forming a preliminary pattern on the outer circumferential surface of the roller, and allowing the preliminary pattern to adhere to the substrate.

### RELATED APPLICATIONS

This application claims the benefit of Korea Patent Application No. 10-2008-0118211 filed on Nov. 26, 2008, the entire contents of which is incorporated herein by reference for all purposes as if fully set forth herein.

### BACKGROUND

1. Field of the Invention

This disclosure relates to an ink composition used for a roll printing process and a method of fabricating a pattern on a substrate using the ink composition.

2. Discussion of the Related Art

In a conventional liquid crystal display (LCD) panel, thin film patterns are formed by a photolithography process and an etching process. However, the photolithography process includes a plurality of processes such as an exposure process, a development process, a cleaning process, and a test process so that the manufacturing cost of the LCD panel is increased. Thus, a method of patterning a thin film by a reverse resist printing method has been recently used instead of the photolithography process.

### BRIEF SUMMARY

According to one general aspect of the present disclosure, an ink composition used in a roll printing process comprises polymer or oligomer, a rosin ester based tackifier according to a chemical formula, and solvent, wherein the chemical formula is

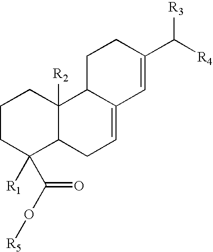

and each of R1, R2, R3, R4, and R5 is selected from a group consisting of hydrogen, an alkyl group, an aryl group, an alkoxy group, and an ester group.

According to another general aspect of the present disclosure, a method of forming a pattern on a substrate comprises forming an ink composition layer including polymer or oligomer, a rosin ester based tackifier according to a chemical formula, and solvent, on an outer circumferential surface of a roller, forming a preliminary pattern on the outer circumferential surface of the roller by rolling the roller on a printing plate on which a print pattern is formed, and allowing the preliminary pattern to adhere to the substrate by rolling the roller on which the preliminary pattern is formed on the substrate.

Other systems, methods, features and advantages will be, or will become, apparent to one with skill in the art upon examination of the following figures and detailed description. It is intended that all such additional systems, methods, features and advantages be included within this description, be within the scope of the invention, and be protected by the following claims. Nothing in this section should be taken as a limitation on those claims. Further aspects and advantages are discussed below in conjunction with the embodiments. It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the embodiments and are incorporated in and constitute a part of this application, illustrate embodiment(s) of the invention and together with the description serve to explain the disclosure. In the drawings:

FIGS. 1-4 illustrate the process of forming a thin film pattern on a substrate according to an embodiment of the present disclosure;

FIG. 5 illustrates a state of the mask pattern #1 according to an experiment example being exposed to an etching solution; and

FIG. 6 illustrates a state of the mask pattern #2 according to a comparative example being exposed to an etching solution.

### DETAILED DESCRIPTION OF THE DRAWINGS AND THE PRESENTLY PREFERRED EMBODIMENTS

Reference will now be made in detail to the embodiments of the present disclosure, examples of which are illustrated in the accompanying drawings. These embodiments introduced hereinafter are provided as examples in order to convey their spirits to the ordinary skilled person in the art. Therefore, these embodiments might be embodied in a different shape, so are not limited to these embodiments described here. Also, the size and thickness of the device might be expressed to be exaggerated for the sake of convenience in the drawings. Wherever possible, the same reference numbers will be used throughout this disclosure including the drawings to refer to the same or like parts.

An ink composition for a roll printing process according to an embodiment of the present disclosure includes base polymer, a rosin ester based tackifier, carrier solvent, a crosslinking agent, and a coloring agent. Examples of the base polymer are a cresol based resin, a phenol based resin, an acryl based resin, an epoxy based resin, and novolac. The base polymer is mixed at a rate of about 4-20 wt %, preferably about 10-15 wt %. Also, oligomer may be used instead of the base polymer. In the present embodiment, the tackifier may have a structure of Chemical Formula 1.

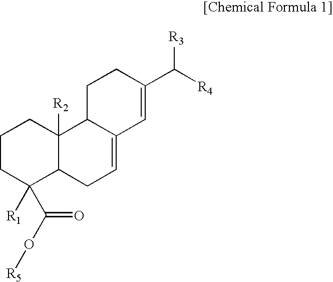

In Chemical Formula 1, R1 is selected from a group consisting of hydrogen, an alkyl group, an aryl group, an alkoxy group, and an ester group. In detail, R1 may be a methyl group. R2 is selected from a group consisting of hydrogen, an alkyl group, an aryl group, an alkoxy group, and an ester group. In detail, R2 may be a methyl group. R3 is selected from a group consisting of hydrogen, an alkyl group, an aryl group, an alkoxy group, and an ester group. In detail, R3 may be a methyl group. R4 is selected from a group consisting of hydrogen, an alkyl group, an aryl group, an alkoxy group, and an ester group. In detail, R4 may be a methyl group. R5 is selected from a group consisting of hydrogen, alkyl group, an aryl group, an alkoxy group, and an ester group. In detail, R5 may be a propyl group that is replaced or not replaced.

The tackifier improves the adhesion characteristic of the ink composition. Also, the tackifier enforces the combination of the base polymer. That is, the combination of the base polymer is enforced by the ester group included in the rosin ester based tackifier. The tackifier may be mixed at a rate of about 2-15 wt %. The tackifier has a molecular weight of about 300-2000.

The rosin ester based tackifier may be formed by the ester reaction of rosin and alcohol as shown below. In the reaction, sulfuric acid may be used as a catalyst.

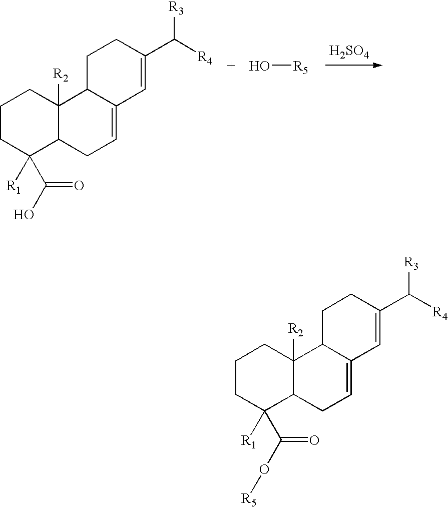

In the present embodiment, the tackifier may be propane-1,2,3,-triol rosin ester of Chemical Formula 2.

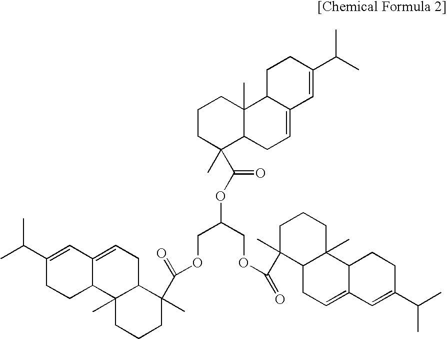

The propane-1,2,3,-triol rosin ester may be formed by the ester reaction of rosin and propane-1,2,3,-triol.

In the present embodiment, the tackifier may be a triethylene glycol rosin ester of Chemical Formula 3.

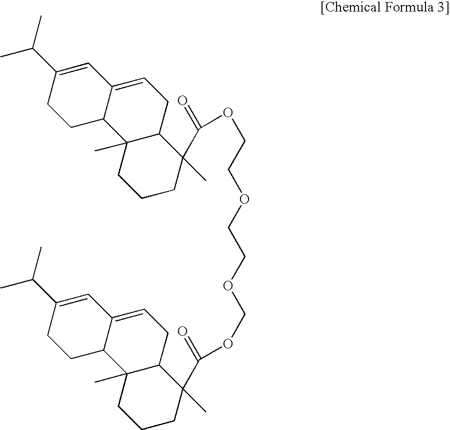

In the present embodiment, the tackifier may be a methanol rosin ester of Chemical Formula 4.

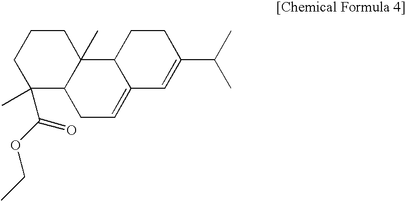

In the present embodiment, the tackifier may be a pentaerythritol rosin ester of Chemical Formula 5.

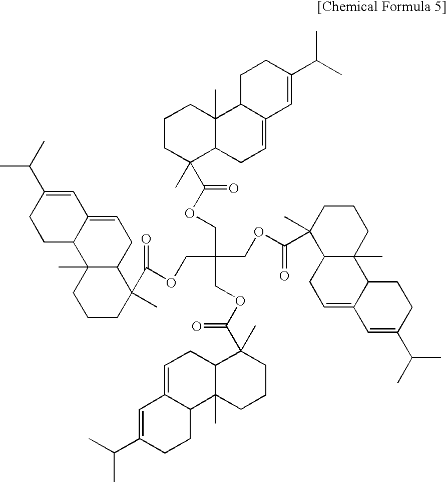

The carrier solvent reduces the viscosity of an ink composition to help the ink composition uniformly coated. The carrier solvent has a low boiling point. Thus, the carrier solvent may be easily volatilized.

The carrier solvent is alcohol based. Examples of the carrier solvent are methanol, ethanol, N-methyl pyrrolidinone, ethyl benzoate, and tri-isoprophyl benzene. The carrier solvent has a low boiling point. The carrier solvent is mixed at a rate of about 40-70 wt %, preferably about 60-65 wt %.

A printing solvent improves adhesion of the ink composition. An example of the printing solvent is propylene carbonate. The boiling point of the printing solvent is higher than that of the carrier solvent. The printing solvent is mixed at a rate of about 20-40 wt %, preferably about 7-8 wt %.

The crosslinking agent crosslinks the base polymer by a heat treatment process. Thus, the crosslinking agent improves the coupling characteristic of an organic film formed by the ink composition. An example of a material used for the crosslinking agent may be melamine derivatives such as melamine formaldehyde. The crosslinking agent is mixed at a rate of about 0.5-3 wt %, preferably about 7-1.5 wt %.

The coloring agent provides the organic film formed by the ink composition with a characteristic of being colored. Accordingly, the defectiveness of the organic film may be easily identified with the naked eye. An example, of a material used for the coloring agent may be dyes or pigments. The coloring agent is mixed at a rate of about 0.1-1.0 wt %, preferably about 0.3-0.6 wt %.

The ink composition according to the present embodiment includes the rosin ester based tackifier. The ester group included in the rosin ester based tackifier forms crosslink in the base polymer. Thus, the heat-resistant and acid-resistant characteristics of the organic film formed by the ink composition according to the present embodiment are improved. As a result, the ink composition according to the present embodiment may form an organic film having an improved characteristic and a defect-free thin film pattern may be formed using the organic film. That is, the organic film formed by the ink composition according to the present embodiment has improved durability to an etching solution or plasma used to form a thin film pattern and may form a fine thin film pattern.

In the above-described embodiment, when a substrate, film, pattern, roller, or layer is formed “on” or “under” another substrate, film, pattern, roller, or layer, the term “on” or “under” includes all cases of forming “directly” or “indirectly via another constituent element”. Also, the reference to the term “on” or “under” of each constituent element is described with reference to the drawings. In the drawings, the size of each constituent element may be exaggerated for convenience of explanation and does not indicate an actual size.

FIGS. 1-4 illustrate the process of forming a thin film pattern on a substrate according to an embodiment of the present disclosure. Referring to FIG. 1, an ink composition is coated on a roller 100. That is, an ink composition layer 200 is formed on the outer circumferential surface of the roller 100. The roller 100 includes a roller body 110 and a blanket 130. The roller body 110 rotates around a rotation shaft 120. The blanket 130 is arranged on the outer circumferential surface of the roller body 110. The blanket 130 may be formed of a material, for example, polydimethylsiloxane.

The ink composition is sprayed to be coated on the outer circumferential surface of the roller 110. The ink composition includes base polymer, a tackifier, carrier solvent, printing solvent, a crosslinking agent, and a coloring agent. The base polymer, the tackifier, the carrier solvent, the printing solvent, the crosslinking agent, and the coloring agent are uniformly mixed. The characteristic and composition of each of the components are the same as those of the above-described ink composition.

The ink composition is sprayed to be uniformly coated on the outer circumferential surface of the blanket 130. Since the viscosity of the ink composition is reduced by the carrier solvent, the ink composition may be uniformly coated on the outer circumferential surface of the blanket 130 to a very thin thickness.

Then, the carrier solvent included in the ink composition layer 200 is vaporized and removed. The roller 100 rolls on a printing plate 300. The printing plate 300 includes a print pattern 310. The ink composition layer 200 contacts the print pattern 310 and is patterned by the print pattern 310. Accordingly, a preliminary pattern 201 is formed on the outer circumferential surface of the blanket 130.

The preliminary pattern 201 has a shape opposite to that of the print pattern 310. That is, a portion 202 of the ink composition layer 200 contacting the print pattern 310 is removed so that the preliminary pattern 201 may be formed.

Referring to FIG. 2, after the preliminary pattern 201 is formed, the roller 100 rolls on a substrate 400. The substrate 400 may be formed of glass, plastic, or silicon. Also, the substrate 400 includes an etching layer 410. The etching layer 410 may be a metal layer.

The preliminary pattern 201 is transferred to the substrate 400. That is, the preliminary pattern 201 contacts the etching layer 410 and adheres to the substrate 400. In detail, the preliminary pattern 201 is arranged on the etching layer 410. Since the carrier solvent is vaporized and volatilized to be removed, the adhesive strength between the carrier solvent and the blanket 130 decreases. Thus, the preliminary pattern 201 may be easily attached to the substrate 400.

Then, the preliminary pattern 201 is hardened by a heat treatment process so that a mask pattern 203 may be formed on the substrate 400. The preliminary pattern 201 may be heat treated for about three minutes at a temperature of 140-160° C. Then, the preliminary pattern 201 may be additionally heat treated for about three minutes at a temperature of 190-210° C.

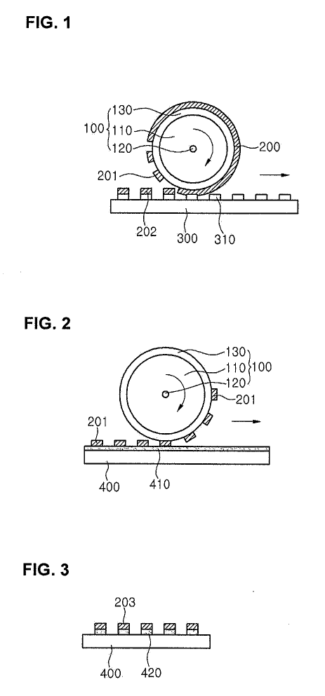

Referring to FIG. 3, the etching layer 410 is patterned using the mask pattern 203 as an etching mask. Accordingly, a thin film pattern 420 is formed on the substrate 400. To pattern the etching layer 410, etching solution or etching gas may be used. Also, the etching solution or the etching gas may have a relatively large selectivity with respect to the etching layer 410.

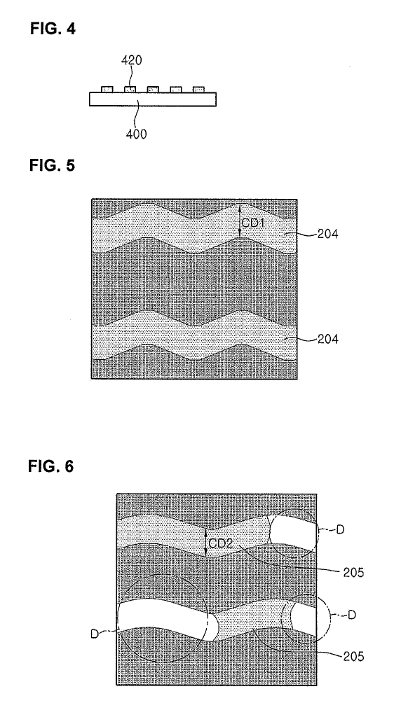

Referring to FIG. 4, after the thin film pattern 420 is formed by patterning the etching layer 410, the mask pattern 203 is removed by plasma. In the present embodiment, since the etching layer 410 is patterned by a roll printing process, not a photolithography process, the thin film pattern 420 may be easily formed. In particular, the roll printing process according to the present embodiment may not need an exposure process. Thus, the TFT array substrates of a semiconductor device and an LCD device or an organic electroluminescence display device may be easily manufactured by the roll printing process.

Also, an organic film such as the mask pattern 203 formed by the ink composition according to the present embodiment exhibits improved heat-resistant, acid-resistant, and peel strength characteristics. That is, the organic film such as the mask pattern 203 exhibits an improved chemical characteristic.

Also, the mask pattern 203 is used as a mask for patterning the etching layer 410. When the etching layer 410 is etched, the mask pattern 203 has improved durability with respect to the etching solution or plasma for etching the etching layer 410. Thus, a portion of the mask pattern 203 is detached from the etching layer 410 or not removed by the etching solution. Accordingly, the etching layer 410 is patterned to a desired thin film pattern 420 and a defective pattern is not formed on the substrate 400. As a result, the ink composition according to the present embodiment and the roll printing process using the ink composition may form more accurate and finer pattern while a defective pattern such as a pattern short-circuit may be prevented.

In the above-described embodiment, a process of forming a mask pattern to pattern the etching layer is described. However, the present disclosure is not limited thereto and the ink composition may be used for forming a pattern of a protection layer or insulation layer, not the mask pattern, constituting a semiconductor device or an LCD device.

Although the present disclosure has been limitedly explained regarding only the embodiments described above, it should be understood by the ordinary skilled person in the art that the present disclosure is not limited to these embodiments, but rather that various changes or modifications thereof are possible without departing from the spirit of the present disclosure. For example, each components disclosed in detail in the present embodiment can be modified or changed. Accordingly, the scope of the present disclosure shall be determined only by the appended claims and their equivalents.

### Experimental Example

Phenol based novolac of about 12.5 wt %, propane-1,2,3,-triol rosin ester of about 12.5 wt %, methanol of about 66 wt %, propylene carbonate of about 7 wt %, melamine of about 1.5 wt %, and a coloring agent of about 0.5 wt % were uniformly mixed to form an ink composition #1. Then, a preliminary pattern #1 was formed on an aluminum layer using the ink composition #1 by a roll print process. The preliminary pattern #1 was heat treated for about three minutes at a temperature of about 200° C., thus forming a mask pattern #1.

### Comparative Example

In the experimental example, butylated hydroxyl anisole was mixed at the same rate instead of the propane-1,2,3,-triol rosin ester, thus forming an ink composition #2. Also, a mask pattern #2 having the same shape as that of the mask pattern #1 was formed in the same conditions in the experiment example.

FIGS. 5 and 6, respectively, illustrate the states of the mask pattern #1 204 and the mask pattern #2 205 after the mask patterns #1 and #2 are exposed to MA-S01B, that is, an etching solution for etching the aluminum layer, by Dongwoo Fine-Chem Co., Ltd. Referring to FIGS. 5 and 6, it can be send that the width CD2 of the mask pattern #2 205 exposed to the etching solution is smaller than the width CD1 of the mask pattern #1 204 exposed in the same condition. Also, a damage D is generated in the mask pattern #2 205 so that short-circuit may be generated in an aluminum thin film pattern according to the comparative example. In contrast, no damage is generated in the mask pattern #1 204 so that short-circuit may not be generated in the aluminum thin film pattern.

As describe above the ink composition according to the present embodiment includes the rosin ester based tackifier. Thus, the tackifier crosslinks polymer and oligomer so that the heat-resistant, acid-resistant, and peel strength characteristics of the organic film formed by the ink composition may be improved.

Accordingly, the mask pattern is formed on the substrate using the ink composition according to the present embodiment. Also, a thin film pattern may be formed on the substrate using the mask pattern so that a defect of the thin film pattern may be reduced. That is, the short-circuit of wiring formed on the substrate may be prevented.

Furthermore, the organic film pattern may be directly formed on the substrate using the ink composition according to the present embodiment. Accordingly, the organic film pattern may be used as a constituent element of a device.

1. An ink composition used in a roll printing process, the ink composition comprising:
polymer or oligomer;
a rosin ester based tackifier according to a chemical formula; and
a solvent,
wherein the chemical formula is 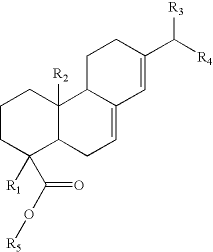
and each of R1, R2, R3, R4, and R5 is selected from a group consisting of hydrogen, an alkyl group, an aryl group, an alkoxy group, and an ester group.

2. The ink composition claimed as claim 1, wherein the tackifier is selected from a group consisting of propane-1,2,3,-triol rosin ester, triethylene glycol rosin ester, methanol rosin ester, and pentaerythritol rosin ester.

3. The ink composition claimed as claim 1, wherein the polymer or oligomer is selected from a group consisting of a phenol based polymer, a phenol based oligomer, a cresol based polymer, and a cresol based oligomer.

4. The ink composition claimed as claim 1, wherein the solvent comprises:
a carrier solvent; and
a printing solvent having a boiling point higher than that of the carrier solvent.

5. The ink composition claimed as claim 1, comprising a coloring agent having a color.

6. A method of forming a pattern on a substrate, the method comprising:
forming an ink composition layer including polymer or oligomer, a rosin ester based tackifier according to a chemical formula, and a solvent, on an outer circumferential surface of a roller;
forming a preliminary pattern on the outer circumferential surface of the roller by rolling the roller on a printing plate on which a print pattern is formed; and
allowing the preliminary pattern to adhere to the substrate by rolling the roller on which the preliminary pattern is formed on the substrate,
wherein the chemical formula is 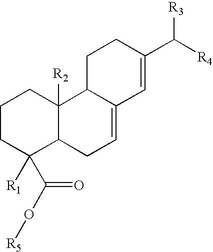
and each of R1, R2, R3, R4, and R5 is selected from a group consisting of hydrogen, an alkyl group, an aryl group, an alkoxy group, and an ester group.

7. The method claimed as claim 6, further comprising heat treating the substrate to which the preliminary pattern adheres.

8. The method claimed as claim 6, wherein the tackifier is selected from a group consisting of propane-1,2,3,-triol rosin ester, triethylene glycol rosin ester, methanol rosin ester, and pentaerythritol rosin ester

9. The method claimed as claim 6, wherein the solvent comprises:
a carrier solvent; and
a printing solvent having a boiling point higher than that of the carrier solvent, and the method further comprising vaporizing the carrier solvent after forming the preliminary pattern.

10. The method claimed as claim 6, wherein the substrate comprises an etching layer, and the method further comprising etching the etching layer using the preliminary pattern as a mask.
